(19) United States
(12) Patent Application Publication
(10) Pub. No.: US 2016/0071893 A1
(43) Pub. Date: Mar. 10, 2016

(54) IMAGING DEVICE AND IMAGING SYSTEM

(71) Applicant: CANON KABUSHIKI KAISHA, Tokyo (JP)

(72) Inventor: Mahito Shinohara, Tokyo (JP)

(21) Appl. No.: 14/838,517

(22) Filed: Aug. 28, 2015

(30) Foreign Application Priority Data
Sep. 8, 2014 (JP) 2014-182273

(51) Int. Cl. H01L 27/146

(52) U.S. Cl. CPC H01L 27/14605; H01L 27/14645; H01L 27/14627

(57) ABSTRACT

An imaging device includes pixel regions including first pixel regions arranged at every other pixel in each row so that the first pixel regions alternate with each other in adjacent rows and configured to convert light in first color into first signal charge and accumulate it, second pixel regions arranged in square lattice form and at positions different from the first pixel regions and configured to convert light in color different from the first color into second signal charge and accumulate it, and third pixel regions arranged in square lattice form and at positions different from the first and second pixel regions and having reading-out circuit unit configured to add the signal charges accumulated in at least two first or second pixel regions adjacent to the third pixel region corresponding to a same color and to output signal based on amount of the added signal charges.

### BACKGROUND OF THE INVENTION

1. Field of the Invention

The present invention relates to an imaging device and an imaging system and particularly to an imaging device that outputs a pixel signal amplified by an MOS transistor in a pixel and an imaging system using it.

2. Description of the Related Art

In a solid-state imaging device, when a pixel signal is to be read out from an imaging region in which a large number of pixels are arrayed, a method of reading out by adding the pixel signals from a plurality of pixels and compressing resolution information of an image is known.

A CCD which is one of the solid-state imaging devices sequentially transfers signal charge of each pixel and outputs it. When the signals of the plural pixels are to be added, the output is basically the added charges (hereinafter this reading-out method will be referred to as a “charge addition”). On the other hand, a CMOS sensor which is another one of the solid imaging devices converts the signal charge of each pixel to a voltage and amplifies the voltage by the MOS transistor and then, outputs it. When the signals of the plural pixels are to be added, the output is basically the added voltage (hereinafter this reading-out method will be referred to as “voltage addition”) or an averaged voltage.

Here, the charge addition in an SN ratio after the signal addition is known to be more excellent than the voltage addition in general. The reason for that is, while the signal charge is transferred as it is and then, added in the charge addition, the voltage amplified by an amplifier transistor is added in the voltage addition and thus, a noise of the amplifier transistor superposed on each signal is also added. Thus, in the CMOS sensor, too, the charge addition is more preferred than the voltage addition for the signal addition.

Moreover, a reading-out has been accelerated recently by employing a column analog-digital converter. When a pixel signal for one frame is to be read out by adding the signal, if the pixel signal is subjected to the charge addition, reading-out time for one frame can be reduced, but reading-out time cannot be reduced basically in the voltage addition. That is, since the signal charge is added in the pixel in the charge addition, an information amount of the pixel signal to be read out from the pixel region can be compressed. On the other hand, since the signal addition is made after the pixel signal is read out in the voltage addition, even if the information amount of the pixel signal is compressed at this time, reading-out time for one frame cannot be naturally reduced.

As described above, the charge addition is more desirable than the voltage addition as an adding method of the pixel signal from the viewpoint of both the SN ratio and the reading-out time for one frame.

A Bayer arrangement described in Japanese Patent Application Laid-Open No. 2001-250931 and Japanese Patent Application Laid-Open No. 2003-244712 is used as pixel arrangements for each color of the CMOS sensor in general. In the Bayer arrangement, the pixels in the same color are arranged separately at every other pixel in a row direction and a column direction even if they are the closest to each other.

However, the signal addition in the CMOS sensor is basically addition of the pixels in the same color. That is because, if a signal of a pixel in a different color is mixed, information of the color is lost, and the color cannot be reproduced any longer. Thus, it has been difficult to realize such pixel constitution capable of the charge addition between the pixels in the same color while basic characteristics of the pixel such as sensitivity and saturated signal charge are maintained.

### SUMMARY OF THE INVENTION

An object of the present invention is to provide an imaging device capable of charge-addition reading-out of plural pixels in the same color while the basic characteristics of the pixel are maintained. Another object of the present invention is to provide an imaging system capable of obtaining an image with reduced noise by using such imaging device.

According to one aspect of the present invention, there is provided an imaging device including a plurality of pixel regions arranged in a matrix including a plurality of rows and a plurality of columns, wherein the plurality of pixel regions includes a plurality of first pixel regions arranged at every other pixel in each row so that the plurality of first pixel regions alternate with each other in adjacent rows, each of the plurality of first pixel regions being configured to convert light in a first color into a first signal charge and accumulate the first signal charge, a plurality of second pixel regions arranged in a square lattice form and at positions different from those of the first pixel regions, each of the plurality of second pixel regions being configured to convert light in a second color or a third color different from the first color into a second signal charge and accumulate the second signal charge, and a plurality of third pixel regions arranged in a square lattice form and at positions different from those of the first pixel regions and the second pixel regions, each of the plurality of third pixel regions having a first reading-out circuit unit configured to add the first signal charge accumulated in at least two first pixel regions adjacent to the third pixel region or add the second signal charge accumulated in at least two second pixel regions corresponding to a same color and being adjacent to the third pixel region and to output a signal based on an amount of added signal charges.

Further features of the present invention will become apparent from the following description of exemplary embodiments with reference to the attached drawings.

### BRIEF DESCRIPTION OF THE DRAWINGS

FIG. 1 is a plan view illustrating a constitution of an imaging device according to a first embodiment of the present invention.

FIGS. 2A, 2B and 2C are circuit diagrams illustrating the constitution of the imaging device according to the first embodiment of the present invention.

FIG. 3 is a plan view illustrating the constitution of the imaging device according to the first embodiment of the present invention.

FIG. 4 is a plan view illustrating the constitution of the imaging device according to the first embodiment of the present invention.

FIG. 5 is a plan view illustrating a constitution of an imaging device according to a second embodiment of the present invention.

FIG. 6 is a diagrammatic cross-sectional view illustrating the constitution of the imaging device according to the second embodiment of the present invention.

FIG. 7 is a diagrammatic cross-sectional view illustrating a constitution of an imaging device according to a third embodiment of the present invention.

FIG. 8 is a plan view illustrating a constitution of an imaging device according to a fourth embodiment of the present invention.

FIG. 9 is a diagrammatic cross-sectional view illustrating the constitution of an imaging device according to the fourth embodiment of the present invention.

FIG. 10 is a diagrammatic view illustrating a constitution of an imaging system according to a fifth embodiment of the present invention.

### DESCRIPTION OF THE EMBODIMENTS

Preferred embodiments of the present invention will now be described in detail in accordance with the accompanying drawings.

### First Embodiment

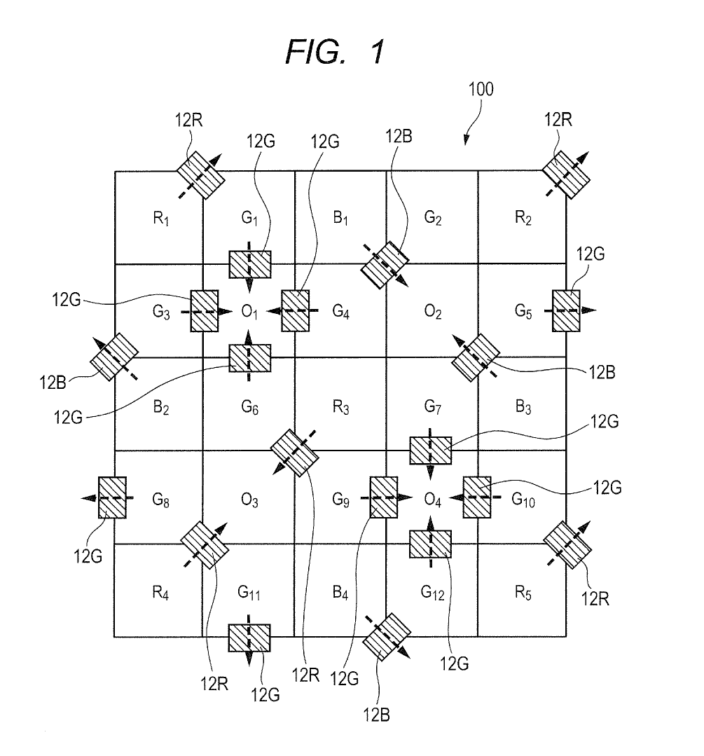

An imaging device according to a first embodiment of the present invention will be described with reference to FIGS. 1 to 4.

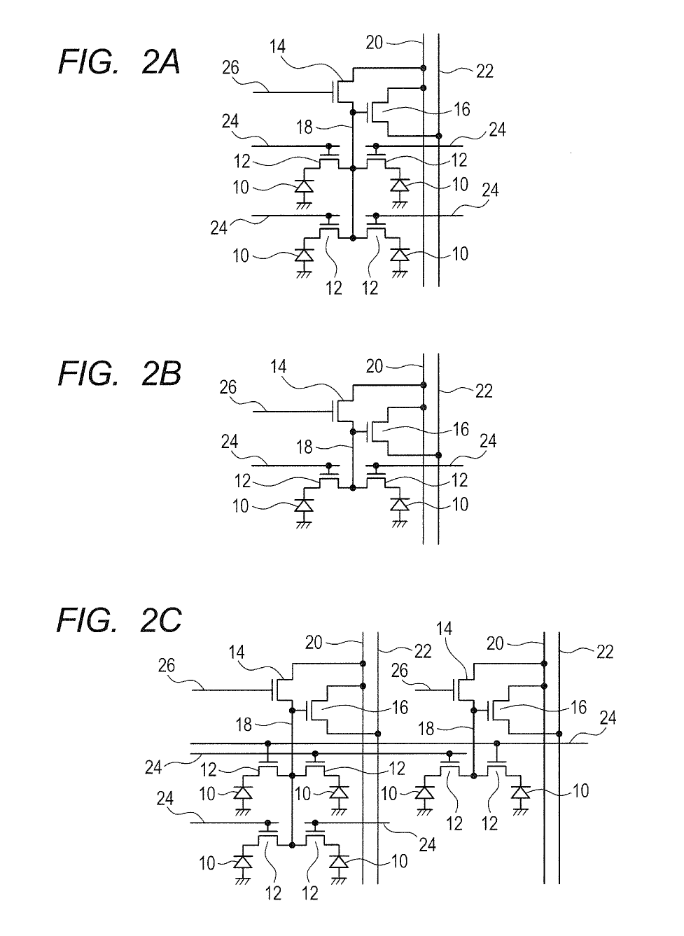

FIGS. 1, 3 and 4 are plan views illustrating a constitution of the imaging device according to the present embodiment. FIGS. 2A, 2B and 2C are circuit diagrams illustrating the constitution of the imaging device according to the present embodiment.

The imaging device 100 according to the present embodiment has a plurality of pixel regions R₁ to R₅, G₁ to G₁₂, B₁ to B₄ and O₁ to O₄ in an imaging region as illustrated in FIG. 1. These plural pixel regions R₁ to R₅, G₁ to G₁₂, B₁ to B₄ and O₁ to O₄ are arranged in a matrix including a plurality of rows and a plurality of columns. Each row crosses each of the plurality of columns. Each column crosses each of the plurality of rows.

The plurality of pixel regions R₁ to R₅, G₁ to G₁₂, B₁ to B₄ and O₁ to O₄ include pixel regions for accumulating a signal charge (hereinafter referred to as a “signal accumulating pixel”) and pixel regions for amplifying and reading out a signal (hereinafter referred to as a “signal reading-out pixel”). In FIG. 1, the pixel regions R₁ to R₅, the pixel regions G₁ to G₁₂ and the pixel regions B₁ to B₄ correspond to the signal accumulating pixels. The pixel regions R₁ to R₅ are pixel regions for accumulating the signal charge by red light (hereinafter referred to as an “R-signal accumulating pixel”). The pixel regions G₁ to G₁₂ are pixel regions for accumulating the signal charge by green light (hereinafter referred to as a “G-signal accumulating pixel”). The pixel regions B₁ to B₄ are pixel regions for accumulating the signal charge by blue light (hereinafter referred to as a “B-signal accumulating pixel”). The pixel regions O₁ to O₄ correspond to the signal reading-out pixels.

In the imaging device according to the present embodiment, a pixel array unit as a repetition unit constituting the image pickup region is 4 rows×4 columns. FIG. 1 illustrates a pixel array of 5 rows×5 columns to facilitate understanding of a pattern of signal charge transmission. By repeatedly arranging the pixel array of such repetition unit in a column direction and a row direction, the image pickup region with a desired number of pixels is constituted.

Subsequently, arrangement of each pixel region will be described more specifically. Here, for convenience of description, the upper left pixel region R₁ in FIG. 1 is assumed to be a pixel region on a first row and a first column, and a row number increases as it goes downward and a column number increases as it goes to the right. For example, the pixel region G₇ is a pixel region on the third row and the fourth column.

The G-signal accumulating pixels (pixel regions G₁ to G₁₂) are arranged in a checkered pattern in a pixel area. That is, the G-signal accumulating pixels are arranged at every other pixel in each row and in each column. They are also arranged so as to alternate in adjacent rows or adjacent columns. In the example in FIG. 1, the pixel regions G are arranged in odd-numbered row and even-numbered column pixel regions and in even-numbered row and odd-numbered column pixel regions.

The R-signal accumulating pixels (pixel regions R₁ to R₅) as well as the B-signal accumulating pixels (pixel regions B₁ to B₄) and the signal reading-out pixels (pixel regions O₁ to O₄) are arranged alternately on every other row and every other column. That is, in the example in FIG. 1, the R-signal accumulating pixels and the B-signal accumulating pixels are arranged alternately in the pixel regions between the G-signal accumulating pixels on odd-numbered rows. And the signal reading-out pixel O is arranged in each of the pixel regions between the G-signal accumulating pixels on even-numbered rows. The pixel region R and the pixel region B are arranged alternately in the pixel regions between the G-signal accumulating pixels on odd-numbered columns. The signal reading-out pixel O is arranged in each of the pixel regions between the G-signal accumulating pixels on even-numbered columns.

When the R-signal accumulating pixels (pixel regions R₁ to R₅) and the B-signal accumulating pixels (pixel regions B₁ to B₄) are considered in a group, these pixel regions are considered to be arrayed in a square lattice form and at positions different from that of the G-signal accumulating pixel. The R-signal accumulating pixels (pixel regions R₁ to R₅) and the B-signal accumulating pixels (pixel regions B₁ to B₄) can be considered to be arranged in a staggered manner in every three pixels in the row direction and the column direction when seen from the entire imaging region. The signal reading-out pixels (pixel regions O₁ to O₄) can be considered to be arranged in the square lattice form and at positions different from those of the signal accumulating pixels.

In FIG. 1, the pixel region O₁ is the signal reading-out pixel for reading out the signal charge accumulated in the pixel regions G₁, G₃, G₄ and G₆ (hereinafter referred to as a “G-signal reading-out pixel”). A transfer gate electrode 12G is arranged each between the pixel region O₁ and the pixel regions G₁, G₃, G₄ and G₆. The pixel region O₄ is the G-signal reading-out pixel for reading out the signal charge accumulated in the pixel regions G₇, G₉, G₁₀ and G₁₂. A transfer gate electrode 12G is arranged each between the pixel region O₄ and the pixel regions G₇, G₉, G₁₀ and G₁₂. The pixel region O₂ is the signal reading-out pixel for reading out the signal charge accumulated in the pixel regions B₁ and B₃ (hereinafter referred to as a “B-signal reading-out pixel”). A transfer gate electrode 12B is arranged each between the pixel region O₂ and the pixel regions B₁ and B₃. The pixel region is the signal reading-out pixel for reading out the signal charge accumulated in the pixel regions R₃ and R₄ (hereinafter referred to as a “R-signal reading-out pixel”). A transfer gate electrode 12R is arranged each between the pixel region O₃ and the pixel regions R₃ and R₄. Arrows illustrated superposing on the transfer gate electrodes 12R, 12G and 12B in FIG. 1 indicate reading-out directions of the signal charges from the signal accumulating pixels to the signal reading-out pixels. In FIG. 1, description on constituent elements in each pixel region other than the transfer gate electrodes 12R, 12G and 12B is omitted.

FIG. 2A is an example of a circuit constituting the G-signal accumulating pixel and its signal reading-out pixel. In the example in FIG. 1, the pixel regions G₁, G₃, G₄ and G₆ and the pixel region O₁ or the pixel regions G₇, G₉, G₁₀ and G₁₂ and the pixel region O₄ correspond to them.

To the G-signal reading-out pixel (pixel region O₁/pixel region O₄), four G-signal accumulating pixels (pixel regions G₁, G₃, G₄ and G₆/pixel regions G₇, G₉, G₁₀ and G₁₂) are adjacent. Each of the four G-signal accumulating pixels has a photodiode 10 which is a photoelectric conversion element. The signal reading-out pixel has four transfer MOS transistors 12, a reset MOS transistor 14 and an amplifier MOS transistor 16. The transfer MOS transistor 12, the reset MOS transistor 14 and the amplifier MOS transistor 16 constitute a reading-out circuit unit.

The photodiode 10 of the G-signal accumulating pixel has an anode grounded and a cathode connected to a source of the transfer MOS transistor 12 of the signal reading-out pixel. The photodiodes 10 of the four G-signal accumulating pixels are connected to separate transfer MOS transistors 12 of the signal reading-out pixel. Drains of the four transfer MOS transistors 12 are connected to a source of the reset MOS transistor 14 and a gate of the amplifier MOS transistor 16. A connection node of the drains of the transfer MOS transistors 12, the source of the reset MOS transistor 14 and the gate of the amplifier MOS transistor 16 constitutes a floating diffusion node (hereinafter referred to as an “FD node”) 18. The drains of the reset MOS transistor 14 and the amplifier MOS transistor 16 are connected to a voltage supply line 20 for supplying a reset voltage for the FD node 18 and a drain voltage of the amplifier MOS transistor 16. A source of the amplifier MOS transistor 16 is connected to a pixel signal output line 22. A gate of the transfer MOS transistor 12 is connected to a transfer gate control signal line 24. A gate of the reset MOS transistor 14 is connected to a reset control signal line 26. The gate of the transfer MOS transistor 12 corresponds to the transfer gate electrode 12G in FIG. 1.

FIG. 2B is an example of a circuit constituting the R-signal accumulating pixel or the B-signal accumulating pixel and its signal reading-out pixel. In the example in FIG. 1, the pixel regions R₃ and R₄ and pixel region O₃ or the pixel regions B₁ and B₃ and the pixel region O₂ correspond to them.

To the R-signal reading-out pixel (pixel region O₃) and the B-signal reading-out pixel (pixel region O₂), two signal accumulating pixels (pixel regions R₃ and R₄/pixel regions B₁ and B₃) to be read out are adjacent in a diagonal direction. Each of these two signal accumulating pixels has the photodiode 10 which is a photoelectric conversion element. The signal reading-out pixel has the two transfer MOS transistors 12, the reset MOS transistor 14 and the amplifier MOS transistor 16. The transfer MOS transistors 12, the reset MOS transistor 14 and the amplifier MOS transistor 16 constitute a reading-out circuit unit.

The photodiode 10 of the signal accumulating pixel has an anode grounded and a cathode connected to the source of the transfer MOS transistor 12 of the signal reading-out pixel. The photodiodes 10 of the two signal accumulating pixels are connected to the separate transfer MOS transistors 12 of the signal reading-out pixel. The drains of the two transfer MOS transistors 12 are connected to the source of the reset MOS transistor 14 and the gate of the amplifier MOS transistor 16. A connection node among the drains of the transfer MOS transistors 12, the source of the reset MOS transistor 14 and the gate of the amplifier MOS transistor 16 constitute the FD node 18. The drains of the reset MOS transistor 14 and the amplifier MOS transistor 16 are connected to the voltage supply line 20 for supplying the reset voltage for the FD node 18 and the drain voltage for the amplifier MOS transistor 16. The source of the amplifier MOS transistor 16 is connected to the pixel signal output line 22. The gate of the transfer MOS transistor 12 is connected to the transfer gate control signal line 24. The gate of the reset MOS transistor 14 is connected to the reset control signal line 26. The gate of the transfer MOS transistor 12 corresponds to the transfer gate electrodes 12R and 12B in FIG. 1.

Names of the source and the drain of the transistor might be different depending on a conductivity type of the transistor or a function in interest but here, they are referred to as typical node names when the NMOS transistor is used. In this case, too, all of or a part of the aforementioned sources and drains might be referred to as opposite names.

FIG. 2C is an example of a circuit in which a part of the transfer gate control signal line 24 is made common in the circuit illustrated in FIG. 2A and the circuit illustrated in FIG. 2B.

In the circuit illustrated in FIG. 2A, the whole of or a part of the four transfer gate control signal lines 24 can be made common. Similarly, in the circuit illustrated in FIG. 2B, the two transfer gate control signal lines 24 can be made common. In the two or more signal reading-out pixels, the whole or a part of the transfer gate control signal lines 24 can be also made common. For example, in the pixel region O₁ and the pixel region O₂ on the second row illustrated in FIG. 1, the whole of or a part of the transfer gate control signal lines 24 may be made common. In the circuit illustrated in FIG. 2C, two of the four transfer gate control signal lines 24 of the G-signal reading-out pixel are made common with the two transfer gate control signal lines 24 of the R-signal reading-out pixel or the B-signal reading-out pixel, respectively.

In reading out of the pixel signal from the pixels constituting the circuits illustrated in FIGS. 2A to 2C, a known method used in a CMOS sensor can be applied. As an embodiment, a method of selective reading-out of a pixel signal by a voltage level of the voltage supply line 20 can be cited. In this method, the voltage supply line 20 and the FD node 18 are connected through the reset MOS transistor 14, and the FD node 18 is reset to a potential according to the voltage of the voltage supply line 20. If the FD node 18 is reset to a high-level potential, a drain current flows through the amplifier MOS transistor 16 of the reading-out pixel, and the pixel signal can be read out. On the other hand, if the FD node 18 is reset to a low-level potential, the amplifier MOS transistor 16 of the reading-out pixel enters a pause state, and the reading-out operation is not performed.

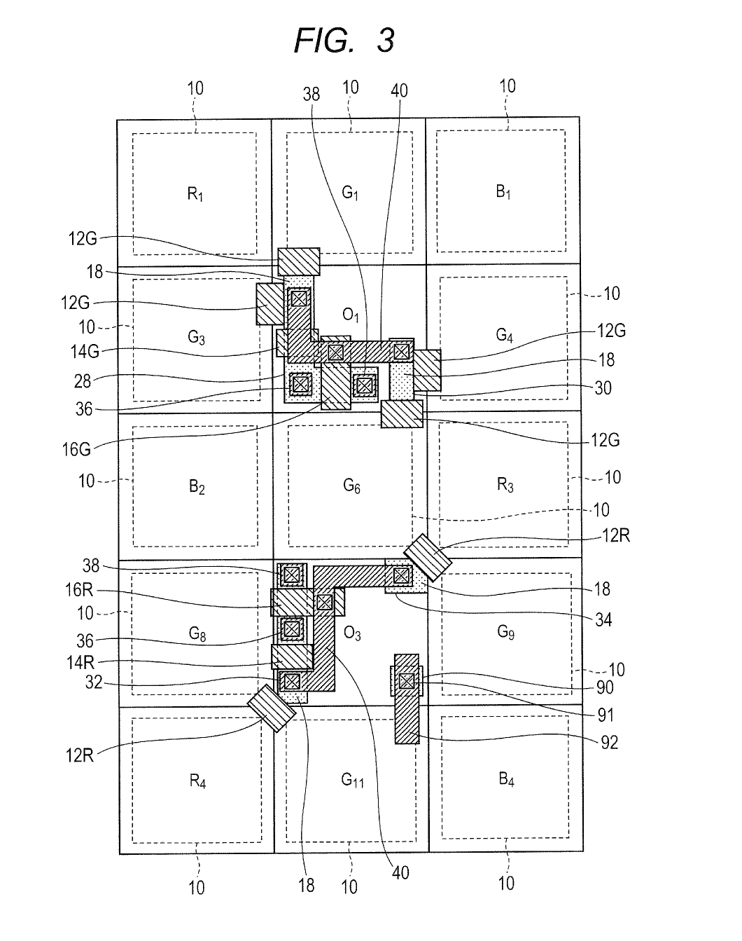

FIG. 3 extracts first to third columns (left 3 columns) from the plan view in FIG. 1 and illustrates the constitution example of each pixel region in more detail. Though not shown here, the same applies to the pixel regions of a fourth column and a fifth column.

In each of the charge accumulating pixels (pixel regions R₁ to R₅, G₁ to G₁₂ and B₁ to B₄), the photodiode 10 is formed. A semiconductor region constituting the anode of the photodiode 10 also constitutes a source region of the transfer MOS transistor 12.

In the G-signal reading-out pixel (pixel regions O₁ and O₄, for example), active regions 28 and 30 defining formation regions (including the FD node 18) of the transfer MOS transistor 12, the reset MOS transistor 14 and the amplifier MOS transistor 16 are provided. More specifically by using the pixel region O₁ as an example, the active region 28 defines the formation regions of the transfer MOS transistor 12 transferring the accumulated charges of the pixel region G₁ and the pixel region G₃, the reset MOS transistor 14 and the amplifier MOS transistor 16. The active region 30 defines the formation region of the transfer MOS transistor 12 transferring the accumulated charges of the pixel region G₄ and the pixel region G₆.

In the signal reading-out pixel (pixel regions O₁ and O₃, for example), an active region 90 is also provided. On a surface of a semiconductor substrate of the active region 90, a highly doped impurity diffused layer of the same conductivity type as a well of the MOS transistor in the pixel, that is, a p-type highly doped impurity diffused layer if the MOS transistor in the pixel is an n-type is formed. To the active region 90, a metal interconnection 92 is connected through a contact portion 91. The contact portion 91 is a plug constituted by metal such as tungsten, for example. As a result, a well potential is supplied to the well of the pixel from the metal interconnection 92 through the contact portion 91. In FIG. 3, the contact portion 91 for well potential supply is provided in the pixel region O₃ with the fewer number of transfer gates than the pixel region O₁, but the contact portion 91 may be naturally provided in both the pixel regions O₁ and O₃.

Above the active region 28, the gate electrode (transfer gate electrode) 12G of the transfer MOS transistor 12, the gate electrode 14G of the reset MOS transistor 14 and the gate electrode 16G of the amplifier MOS transistor 16 are formed. The active region 28 is connected to the active region on which the photodiodes 10 of the pixel region G₁ and the active region on which the pixel region G₃ are formed in the regions under the gate electrodes 12G. Above the active region 30, the gate electrode (transfer gate electrode) 12G of the transfer MOS transistor 12 is formed. The active region 30 is connected to the active region on which the photodiodes 10 of the pixel region G₄ and the active region on which the pixel region G₆ are formed in the regions under the gate electrodes 12G.

A region between the gate electrode 12G and the gate electrode 14G of the active region 28 and the active region 30 constitute the FD node 18. The FD node 18 is connected to the gate electrode 16G of the amplifier MOS transistor 16 through an interconnection 40. In the drain regions of the reset MOS transistor 14 and the amplifier MOS transistor 16 between the gate electrode 14G and the gate electrode 16G of the active region 28, a drain electrode 36 connected to the voltage supply line 20 is provided. In the source region of the amplifier MOS transistor 16, a source electrode 38 connected to the pixel signal output line 22 is provided.

In the R-signal reading-out pixel (pixel region O₃, for example), active regions 32 and 34 defining formation regions (including the FD node 18) of the transfer MOS transistors 12, the reset MOS transistor 14 and the amplifier MOS transistor 16 are provided. More specifically by using the pixel region O₃ as an example, the active region 32 defines the formation regions of the transfer MOS transistor 12 transferring the accumulated charges of the pixel region R₄, the reset MOS transistor 14 and the amplifier MOS transistor 16. The active region 34 defines the formation region of the transfer MOS transistor 12 transferring the accumulated charges of the pixel region R₃.

Above the active region 32, the gate electrode (transfer gate electrode) 12R of the transfer MOS transistor 12, the gate electrode 14R of the reset MOS transistor 14 and the gate electrode 16R of the amplifier MOS transistor 16 are formed. The active region 32 is connected to the active region on which the photodiode 10 of the pixel region R₄ is formed in the region under the gate electrode 12R. Above the active region 34, the gate electrode (transfer gate electrode) 12R of the transfer MOS transistor 12 is formed. The active region 34 is connected to the active region on which the photodiode 10 of the pixel region R₃ is formed in the region under the gate electrode 12R.

A region between the gate electrode 12R and the gate electrode 14R of the active region 32 and the active region 34 constitute the FD node 18. The FD node 18 is connected to the gate electrode 16R of the amplifier MOS transistor 16 through the interconnection 40. In the drain regions of the reset MOS transistor 14 and the amplifier MOS transistor 16 between the gate electrode 14R and the gate electrode 16R of the active region 32, the drain electrode 36 connected to the voltage supply line 20 is provided. In the source region of the amplifier MOS transistor 16, the source electrode 38 connected to the pixel signal output line 22 is provided.

An element constitution of the B-signal reading-out pixel (pixel region O₂, for example) is similar to that of the R-signal reading-out pixel.

The two or four transfer gate electrodes 12R, 12G and 12B arranged on one signal reading-out pixel can be controlled independently. FIG. 3 illustrates the two signal-reading-out pixels (pixel regions O₁ and O₃), but as illustrated in the circuit diagram in FIG. 2C, for example, the pixel signal output line 22 connected to these two signal reading-out pixels may be made separate, and two of the transfer gate control signal lines 24 may be made common. That is, the two transfer gate control signal lines 24 arranged on the signal reading-out pixel (pixel region O₃) on a lower side in FIG. 3 can be made common with two of the four transfer gate control signal lines 24 arranged on the signal reading-out pixel (pixel region O₁) on an upper side. By constituting as above, when signal reading-out of two signal accumulating pixels is to be performed from the upper signal reading-out pixel (pixel region O₁), the signal reading-out from the lower signal reading-out pixel (pixel region O₃) can be made by the common transfer gate control signal line 24 at the same time.

In the imaging device according to the present embodiment, the first pixel regions (pixel regions G₁ to G₁₂) photoelectrically converting light in the first color (green) and accumulating the signal as described above are arranged in the checkered pattern. Specifically, the G pixels are arranged repeatedly at every other pixel in each row and in each column. This is the same as arrangement of the G pixels in the so-called Bayer arrangement.

The pixel regions (pixel regions B₁ to B₄) photoelectrically converting light in the second color (blue) and accumulating the signal and the pixel regions (pixel regions R₁ to R₅) photoelectrically converting light in the third color (red) and accumulating the signal are arranged in a staggered manner. Specifically, the R-signal accumulating pixels and the B-signal accumulating pixels are arranged repeatedly every three pixels in the row direction and the column direction. Alternatively, if these pixel regions (pixel regions B₁ to B₄ and R₁ to R₅) are considered altogether as a second pixel region, these second pixel regions are arranged in the square lattice form and at positions different from those of the first pixel regions.

By arranging the R-signal accumulating pixels, the G-signal accumulating pixels and the B-signal accumulating pixels as above, the G-signal reading-out pixel for reading out the G signals from these G-signal accumulating pixels can be arranged in the adjacent pixel region surrounded by the four G-signal accumulating pixels. Moreover, the R-signal reading-out pixel for reading out the R signals from these R-signal accumulating pixels can be arranged in the adjacent pixel region sandwiched between the two R-signal accumulating pixels located in the diagonal direction. Similarly, the B-signal reading-out pixel for reading out the B signals from these B-signal accumulating pixels can be arranged in the adjacent pixel region sandwiched between the two B-signal accumulating pixels located in the diagonal direction. Fourth pixel regions (pixel regions O₁ to O₄) for signal reading-out arranged as above are arranged in the square lattice form and at the positions different from those of the first pixel regions and the second pixel regions.

That is, the respective signal reading-out pixels are adjacent to this signal reading-out pixel and also capable of reading out signals of a plurality of the pixels allocated to a single color. Specifically, by transferring and reading out a signal charge by one pixel each from the plurality of signal accumulating pixels adjacent to the one signal reading-out pixel, the signal charges of the plurality of signal accumulating pixels in the same color can be read out separately and independently. By transferring and reading out the signal charges at the same time from the plurality of signal accumulating pixels adjacent to the one signal reading-out pixel, the signal charges of the plurality of signal accumulating pixels in the same color can be added and read out.

In the pixel arrangement illustrated in FIG. 1, if the charge addition and reading-out is to be performed by the aforementioned method, the center of gravity of each color of the added signals is in the so-called Bayer arrangement. All the signals of each signal accumulating pixel can be used without disuse of the signal of a specific signal accumulating pixel when the charges are added.

If a focus detecting pixel is to be arranged in an imaging region, a discontinuous portion may be generated in a repetition cycle of the R pixel, the G pixel and the B pixel by using a part of the pixel region for this.

As described above, according to the imaging device of the present embodiment, by arranging the signal accumulating pixels and the signal reading-out pixels as illustrated in FIG. 1, signal charges of the pixels in the same color can be added in the CMOS sensor.

By applying the charge addition reading-out of the four pixels in the same color of the present embodiment to the CMOS sensor employing a column analog-digital converter (hereinafter referred to as a column ADC) having substantially no horizontal transfer time, read-out information from the pixel area becomes 1/4 of the independent reading-out of all the pixels. As a result, the reading-out time of one frame becomes 1/4. Moreover, consumed energy required in a pixel unit in reading-out of one frame becomes 1/4. The SN ratio becomes four times. In the case of the voltage addition reading-out of the four pixels in the same color, the reading-out time and the reading-out energy for one frame are not different from those in the reading-out of all the pixels. The SN ratio only becomes twice.

Moreover, in the imaging device of the present embodiment, by separating the signal accumulating pixels and the signal reading-out pixels from each other, a photodiode area per pixel becomes larger than arrangement of a reading-out circuit with a photodiode in one pixel region, and a saturated signal charge amount increases.

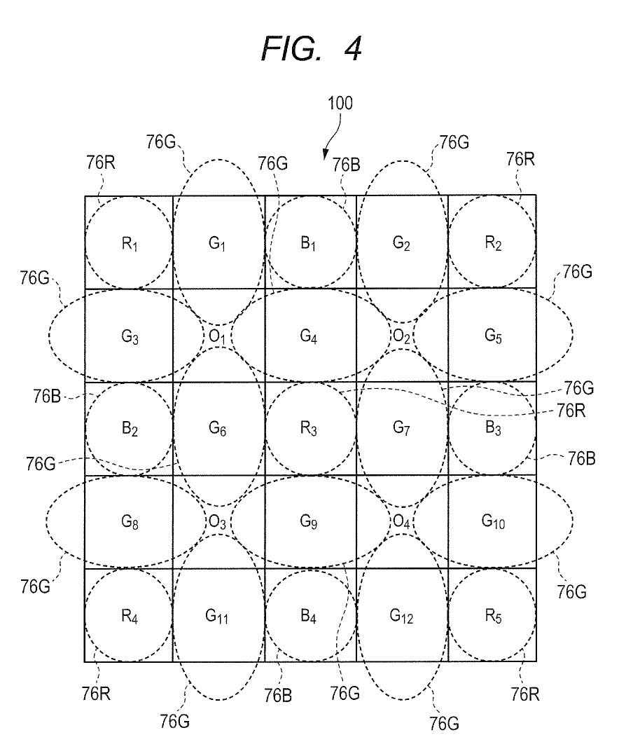

Sensitivity of the imaging device is substantially determined by an area of a micro lens arranged on each pixel region. In the imaging device of the present embodiment, since the signal reading-out element does not perform light detection in principle, there is no particular need to arrange the micro lens in the signal reading-out pixel portion. Therefore, a region above the signal reading-out pixel portion can be assigned to a micro lens 76G for collecting incident light to the G-signal accumulating pixel as illustrated in FIG. 4, for example.

Typically, a size of the micro lens 76G arranged above the G-signal accumulating pixel is the same as a size of a micro lens 76R arranged above the R-signal accumulating pixel and a micro lens 76B arranged above the B-signal accumulating pixel. On the other hand, in an example in FIG. 4, the micro lens 76G for collecting the incident light to the G-signal accumulating pixel is constituted to have an oval shape and arranged so as to extend to upper and lower or right and left signal reading-out pixel portions from the G-signal accumulating pixel portion. By constituting as above, an occupied area of the micro lens 76G for collecting light to the G-signal accumulating pixel can be increased to 1.5 times of a pixel area, and its green sensitivity can be also increased to 1.5 times of the green sensitivity of a pixel with a conventional constitution.

As described above, according to the present embodiment, since charge addition and reading-out can be performed for each of the pixels in the same color, the SN ratio can be improved as compared with the voltage addition and reading-out. Moreover, the pixel reading-out time is reduced, and the number of read-out frames per unit time can be increased. A photodiode area of the signal accumulating pixel can be increased, and sensitivity and a saturated signal amount of the pixel can be improved.

### Second Embodiment

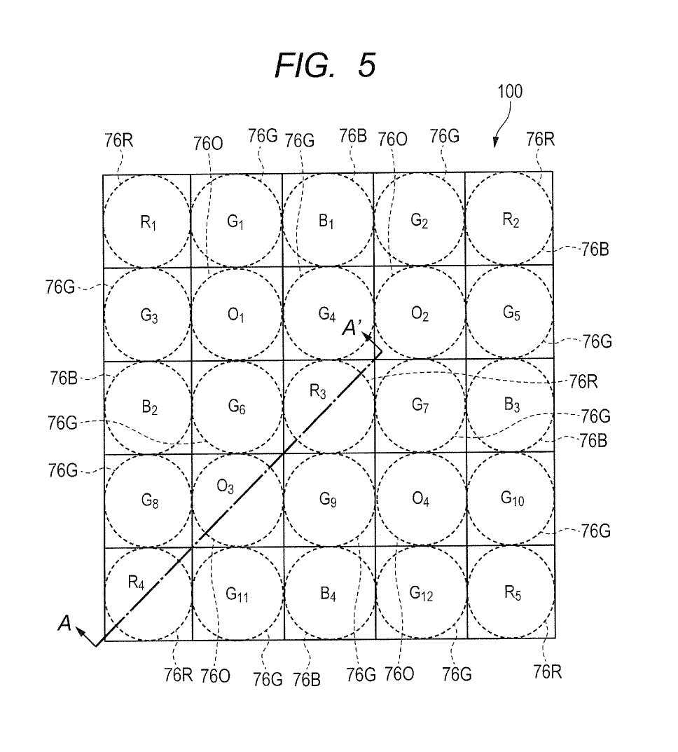

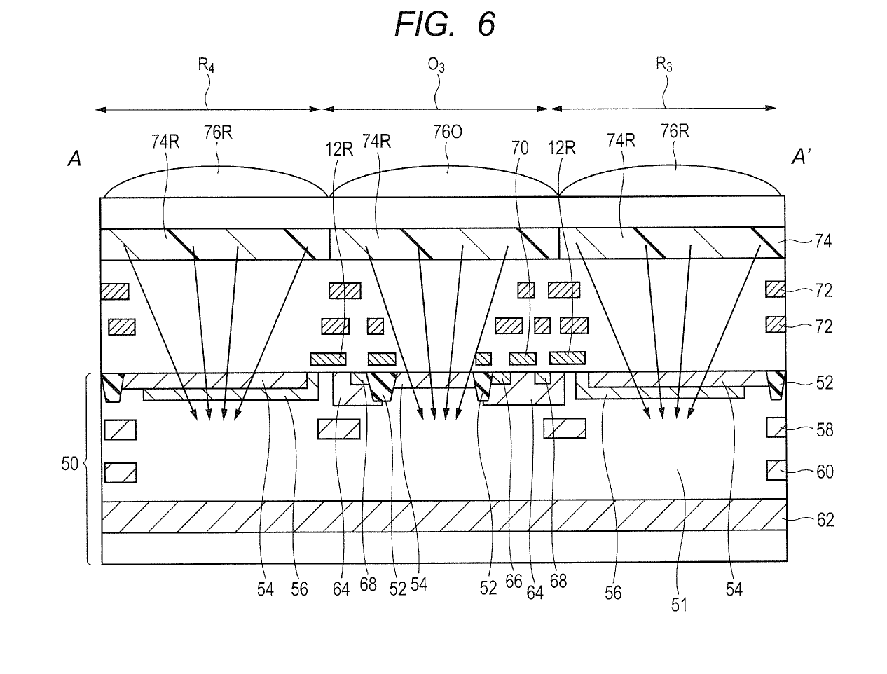

An imaging device according to a second embodiment of the present invention will be described with reference to FIGS. 5 and 6. The same reference numerals are given to constituent elements similar to those in the imaging device according to the first embodiment illustrated in FIGS. 1 to 4 and the description will be omitted or simplified.

FIG. 5 is a plan view illustrating a constitution of the imaging device according to the present embodiment. FIG. 6 is a diagrammatic cross-sectional view illustrating the constitution of the imaging device according to the present embodiment.

In the first embodiment, the fact that light detection is not performed in principle in the signal reading-out pixel is described, but sensitivity can be improved by using also the signal reading-out pixel for light detection.

That is, in the imaging device 100 according to the present embodiment, in addition to the signal accumulating pixel, the signal reading-out pixels (pixel regions O₁ to O₄) are also used for light detection. In order to use the signal reading-out pixels for light detection, a micro lens 76O for collecting light to these pixel regions is arranged above these pixel regions as illustrated in FIG. 5.

In the imaging device 100 according to the present embodiment, the R-signal reading-out pixel (pixel region O₃) in the four signal reading-out pixels included in the pixel array of a repetition unit is used as a pixel for detecting red light. Moreover, the B-signal reading-out pixel (pixel region O₂) is used as a pixel for detecting blue light. Moreover, in the two G-signal reading-out pixels (pixel regions O₁ and O₄), one (pixel region O₁) is used as a pixel for detecting red light, while the other (pixel region O₄) is used as a pixel for detecting blue light.

In this case, a red color filter is provided above the pixel regions O₁ and O₃, and a blue color filter is provided above the pixel regions O₂ and O₄. The R-signal accumulating pixel is arranged adjacently in the diagonal direction of one of the signal reading-out pixels (O₁ to O₄), while the B-signal accumulating pixel is arranged on the other diagonal direction. Therefore, the color of the color filters arranged adjacently in the signal reading-out pixels (O₁ to O₄) is the same color as that of the color filter arranged on the signal accumulating pixel arranged adjacently in either one of the diagonal directions.

The constitution of the imaging device according to the present embodiment will be described in more detail by using FIG. 6. FIG. 6 is a cross-sectional view along A-A′ line in FIG. 5.

A semiconductor substrate 50 includes a semiconductor region 51 of a first conductivity type (n-type, for example) in a surface portion. The semiconductor region 51 may be a part of the semiconductor substrate 50 or may be an impurity diffused layer formed by implanting impurities. Moreover, a conductivity type of the semiconductor region 51 may be a second conductivity type (p-type, for example) opposite to the first conductivity type. In the surface portion of the semiconductor substrate 50, an element isolation insulating layer 52 defining an active region in each pixel region (pixel regions R₃, R₄ and O₃) is provided. In a surface portion of the active region of the signal accumulating pixel (pixel regions R₃, R₄), the photodiode 10 including the second conductivity type impurity diffused layer 54 and a first conductivity type impurity diffused layer 56 arranged beneath a bottom portion of the impurity diffusion layer 54 is formed. The signal charge generated by photoelectric conversion in the photodiode 10 is accumulated in the impurity diffused layer 56. That is, the impurity diffused layer 56 is a charge accumulating portion for accumulating the signal charges.

Second conductivity type impurity diffused layers 58, 60 and 62 are provided in a deep portion of the semiconductor substrate 50. The impurity diffused layer 58 plays a role of isolation between the pixels inside the semiconductor substrate 50. The impurity diffused layer 60 plays a role of isolation between the pixels inside the semiconductor substrate 50 deeper than the impurity diffused layer 58. The impurity diffused layer 62 is to define a depth of a photoelectric conversion unit.

The impurity diffused layers 58 and 60 are arranged between the pixel regions for isolation between the pixels but the impurity diffused layer 60 is not arranged in at least a part of regions between the signal reading-out pixel and the signal accumulating pixel adjacent to this pixel in the diagonal direction and on which the color filter in the same color is arranged. For example, the impurity diffused layer 60 is not arranged in at least a part of the regions between the pixel region O₃ and the pixel regions R₃ and R₄ adjacent to the pixel region O₃ in the diagonal direction and on which the color filter 74R in the same red color is arranged. Similarly, the impurity diffused layer 60 is not arranged, either, in at least a part of the regions between the pixel region O₁ and the pixel regions R₁ and R₃, between the pixel region O₂ and the pixel regions B₁ and B₃ and between the pixel region O₄ and the pixel regions B₃ and B₄. Though not shown here, the impurity diffused layer 60 is arranged between the pixel region O₃ and the pixel regions B₂ and B₄ adjacent to the pixel region O₃ in the other diagonal direction and on which the blue color filter is arranged. Similarly, the impurity diffused layer 60 is arranged between the pixel region O₁ and the pixel regions B₁ and B₂, between the pixel region O₂ and the pixel regions R₂ and R₃ and between the pixel region O₄ and the pixel regions R₃ and R₅.

The signal reading-out pixel (pixel region O₃) includes a reading-out circuit region and a light detection region. In a surface portion of the reading-out circuit region of the pixel region O₃, a second conductivity type impurity diffused layer 64 which becomes a well in which the MOS transistor constituting the reading-out circuit is formed is provided. In the impurity diffused layer 64, a first conductivity type impurity diffused layer 66 which becomes a source/drain region of the MOS transistor and a first conductivity type impurity diffused layer 68 which becomes an FD region are provided. In a surface portion of the light detection region of the pixel region O₃, the second conductivity type impurity diffused layer 54 is provided. In FIG. 6, the second conductivity type impurity diffused layer 64 which becomes a well and the semiconductor region 51 have conductivity types different from each other. However, the both may have the same conductivity type. In this case, a well can be formed inside the semiconductor region 51. Alternatively, a part of or the whole of the semiconductor region 51 may function as a well.

Above the semiconductor substrate 50, a gate interconnection layer 70 including the gate electrode (transfer gate electrode 12R) of the transfer MOS transistor 12 and an interconnection layer 72 for leading out from each electrode of the FD region and the MOS transistor or connecting are provided.

A color filter in the same color as the color filter arranged above the signal accumulating pixel adjacent in either of the diagonal directions is arranged above the signal reading-out pixel as described above. That is, the red color filter 74R is arranged above the pixel regions O₁ and O₃. The blue color filter is arranged above the pixel regions O₂ and O₄. Above the color filters 74, micro lenses 76 (micro lenses 76R, 76G, 76B and 76O) are provided one by one corresponding to the respective pixel regions.

In the imaging device according to the present embodiment, the second conductivity type impurity diffused layer 54 is formed in the light detection region of the signal reading-out pixel, but the first conductivity type impurity diffused layer 56 in which the signal charge is accumulated is not formed. However, the semiconductor substrate 50 has a photoelectric conversion function and generates a signal charge by incidence of light. Moreover, the impurity diffused layer 60 for isolation between the pixels is not arranged in at least a part of a region between the signal reading-out pixel and the signal accumulating pixels adjacent to this pixel in the diagonal direction and with the same color filter color. Specifically, in FIG. 6, neither of the impurity diffused layer 58 and the impurity diffused layer 60 is arranged between the element isolation insulating layer 52 adjacent to the impurity diffused layer 54 and the impurity diffused layer 62. The impurity concentration of the region between the element isolation insulating layer 52 and the impurity diffusion layer 62 is substantially equal to the impurity concentration of a portion under the impurity diffused layer 54 of the semiconductor region 51, for example. Thus, the signal charge generated in the light detection region of the signal reading-out pixel flows into the impurity diffused layer 56 of the signal accumulating pixel adjacent in the diagonal direction and having the same color filter color. As a result, the total accumulated charges of the signal accumulating pixel becomes a total of the signal charges generated in the pixel itself and the signal charges generated in the signal reading-out pixel, and the sensitivity improvement effect can be obtained.

The photodiode 10 arranged in the signal accumulating pixel is arranged in the first conductivity type well (the first conductivity type region of the semiconductor substrate 50 shallower than the impurity diffused layer 62 in FIG. 6). In this well and the impurity diffused layers 58, 60 and 62 for pixel isolation, a contact portion (not illustrated) for applying a predetermined voltage is provided. This contact portion can be arranged in the signal accumulating pixel but is preferably arranged in the signal reading-out pixel. By arranging the contact portion in the signal reading-out pixel, a drop of a light receiving area of the photodiode can be suppressed.

In the imaging device according to the present embodiment, the number of signal reading-out pixels is equal to the numbers of the R-signal accumulating pixels and the B-signal accumulating pixels included in the pixel array of the repetition unit as illustrated in FIG. 1. Therefore, by using a half of the signal reading-out pixels included in the pixel array of the repetition unit for photoelectric conversion of red light and by using the remaining half for the photoelectric conversion of blue light, sensitivities of both blue and red become exactly twice of non-use of the signal reading-out pixel for the photoelectric conversion.

In the original pixels, a ratio of the numbers of the signal accumulating pixels corresponding to each of green, red and blue is 4:1:1 but in the pixels after the same-color charge addition, the ratio of the numbers of the signal reading-out pixels corresponding to each of green, red and blue is 2:1:1. That is because the green signals are 4-pixel addition, and the red and blue signals are 2-pixel addition, respectively. Therefore, by giving the photoelectric conversion function to the signal reading-out pixels as in the present embodiment and by making sensitivities of blue and red twice of no contribution to the sensitivity from the signal reading-out pixel, balance among signal amounts of green, red and blue at charge addition of the same-color pixels is improved. As a result, an image with a better quality can be formed.

As described above, according to the present embodiment, since the charge addition reading-out can be performed for each of the pixels in the same color, the SN ratio can be improved as compared with the voltage addition reading-out. Moreover, the pixel reading-out time is reduced, and the number of read-out frames per unit time can be increased. Moreover, the photodiode area of the signal accumulating pixel can be increased, and the sensitivity and the saturated signal amount of the pixel can be improved. Moreover, the sensitivity of the pixel can be further improved by using also the signal reading-out pixel for the light detection.

### Third Embodiment

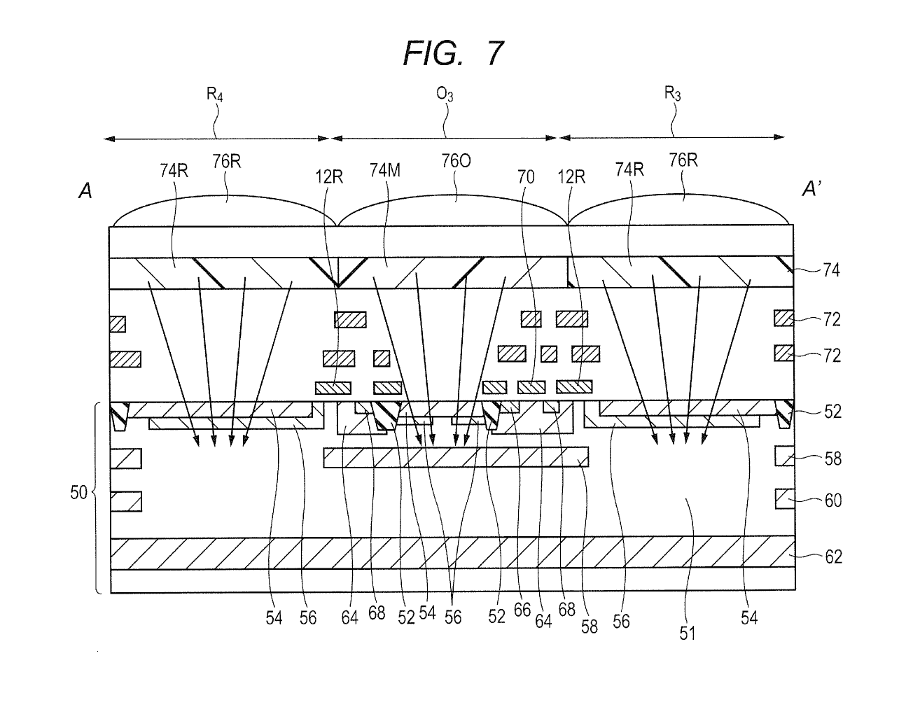

An imaging device according to a third embodiment of the present invention will be described with reference to FIG. 7. The same reference numerals are given to constituent element similar to those in the imaging device according to the first and second embodiments illustrated in FIGS. 1 to 6 and the description will be omitted or simplified.

FIG. 7 is a diagrammatic cross-sectional view illustrating a constitution of the imaging device according to the present embodiment. FIG. 7 is a cross-sectional view along A-A′ line in FIG. 5.

The imaging device according to the present embodiment has, as illustrated in FIG. 7, two first conductivity type impurity diffused layers 56 constituting separate photodiodes together with the second conductivity type impurity diffused layer 54 in the light detection region of the R-signal reading-out pixel (pixel region O₃). Moreover, a reading-out circuit (not shown) for separately reading out the signal charges from these photodiodes in the light detection region is provided in a reading-out region of the R-signal reading-out pixel (pixel region O₃). Moreover, the second conductivity type impurity diffused layer 58 for isolation is arranged over the entire region of the R-signal reading-out pixel (pixel region O₃). Furthermore, a color filter 74M in a magenta color is arranged above the R-signal reading-out pixel (pixel region O₃). The other basic constitutions are similar to those of the imaging device according to the second embodiment illustrated in FIGS. 5 and 6.

The magenta color filter 74M transmits red light and blue light in red light, green light and blue light. In a region shallower than the impurity diffused layer 58, the blue light and the red light having passed through the magenta color filter 74M enters the photodiode, and a signal charge generated by photoelectric conversion is accumulated in the impurity diffused layer 56. Since the light with a short wavelength is absorbed more than the light with a long wavelength in the semiconductor substrate 50, the red light can reach a region deeper than the impurity diffused layer 58 but the blue light can hardly reach the region. Thus, substantially only the red light reaches the region deeper than the impurity diffused layer 58, and a signal charge is generated by photoelectric conversion by the red light. The signal charge generated in this deep region is blocked by the impurity diffused layer 58 and is not accumulated in the impurity diffused layer 56 in the signal reading-out pixel but flows into the R-signal accumulating pixel adjacent to the signal reading-out pixel in the diagonal direction and is accumulated in the impurity diffused layer 56.

As described in Japanese Patent Application Laid-Open No. 2003-244712, information for adjusting a lens focal point can be obtained by arranging a pair of photodiodes in one pixel with one micro lens and by reading out a signal of both or one of the photodiodes. In the imaging device according to the present embodiment, the two photodiodes arranged in the signal reading-out pixel can be used as the pair of photodiodes for focal point detection. Therefore, as in the imaging device according to the present embodiment, a faster automatic focusing (hereinafter referred to as an “AF”) can be realized by further adding the signal reading-out function for focusing to the signal reading-out pixel.

The signal reading-out pixel having the impurity diffused layer 56 used for AF is preferably arranged in the R-signal reading-out pixel or the B-signal reading-out pixel. The G-signal reading-out signal bears outputs from the four G-signal accumulating pixels, while the R-signal reading-out pixel and the B-signal reading-out pixel bear outputs from the two signal accumulating pixels. In reading-out of all the pixels, the G-signal reading-out pixel sequentially reads out the signals of the four pixels. Therefore, by performing signal outputs of the two signal accumulating pixels and the signal output for AF of the pixel itself from the R-signal reading-out pixel and the B-signal reading-out pixel at the same time as above, the reading-out time for all the pixels is not increased even if reading-out of the AF signal is further performed. Moreover, the R-signal reading-out pixel and the B-signal reading-out pixel have fewer transfer gates than the G-signal reading-out pixel, there is a merit that a charge accumulating unit for AF and a reading-out circuit unit can be formed easily.

As described above, according to the present embodiment, since the charge addition reading-out can be performed for each of the pixels in the same color, the SN ratio can be improved as compared with the voltage addition reading-out. Moreover, the pixel reading-out time is reduced, and the number of read-out frames per unit time can be increased. The photodiode area of the signal accumulating pixel can be increased, and the sensitivity and the saturated signal amount of the pixel can be improved. Moreover, the signal reading-out pixel can be used as a pixel for detecting a signal for AF.

### Fourth Embodiment

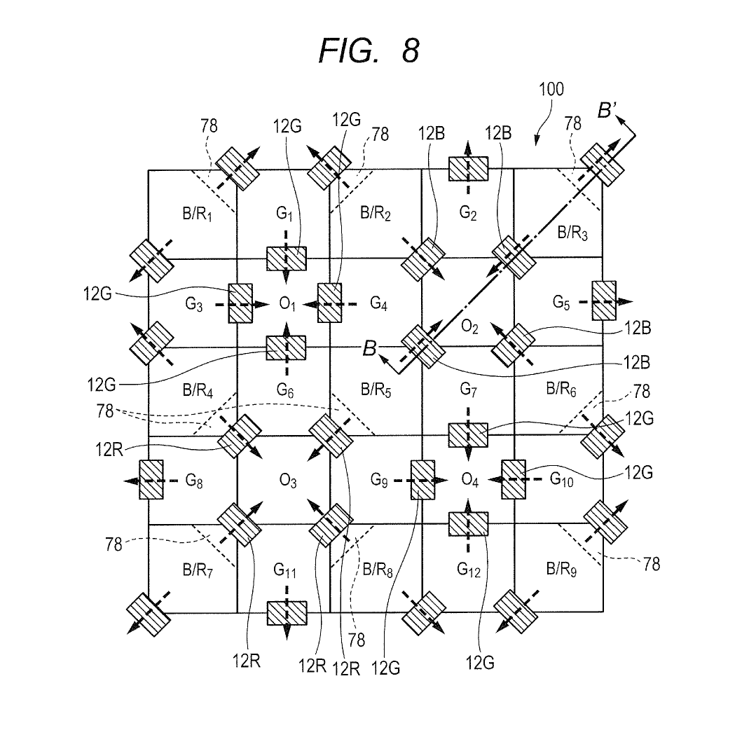

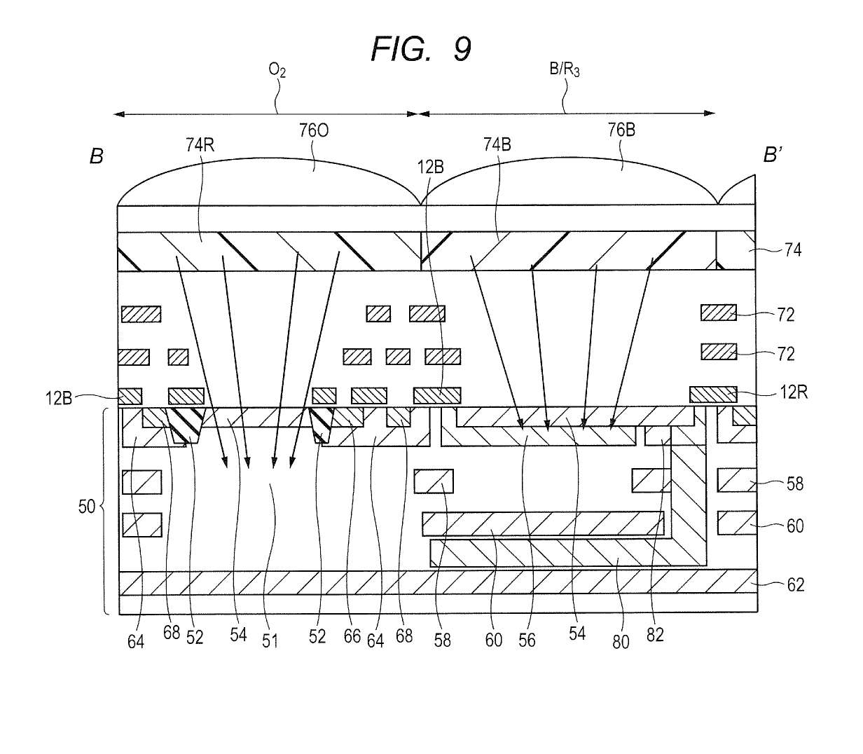

An imaging device according to a fourth embodiment of the present invention will be described with reference to FIGS. 8 and 9. The same reference numerals are given to constituent elements similar to those in the imaging device according to the first to third embodiments illustrated in FIGS. 1 to 7 and the description will be omitted or simplified.

FIG. 8 is a plan view illustrating a constitution of the imaging device according to the present embodiment. FIG. 9 is a diagrammatic cross-sectional view illustrating the constitution of the imaging device according to the present embodiment.

The imaging device 100 according to the present embodiment has, as illustrated in FIG. 8, a plurality of the pixel regions G₁ to G₁₂, B/R₁ to B/R₉ and O₁ to O₄ in an imaging region. Similarly to the previous embodiments, the pixel regions G₁ to G₁₂ are the G-signal accumulating pixels. The pixel regions O₁ to O₄ are the signal reading-out pixels. Arrangement of the pixel regions G₁ to G₁₂ and the pixel regions O₁ to O₄ is also similar to those in the previous embodiments. The pixel regions B/R₁ to B/R₉ are pixel regions for separately accumulating a signal charge by blue light and the signal charge by red light (hereinafter referred to as a “B/R signal accumulating pixel”). Each of the pixel regions B/R₁ to B/R₉ has an outlet portion 78 to be an outlet when the signal charge by the red light is to be transferred. The pixel regions B/R₁ to B/R₉ are arranged in the pixel regions in which the R-signal accumulating pixels and the B-signal accumulating pixels are arranged in the previous embodiments.

The constitution of the imaging device according to the present embodiment will be described in more detail by using FIG. 9. FIG. 9 is cross-sectional view along B-B′ line in FIG. 8.

The signal reading out pixels (pixel regions O₁ to O₄) of the imaging device according to the present embodiment are similar to those of the imaging device according to the second embodiment illustrated in FIG. 6 except that a color filter formed above them is the red color filter 74R. Though not shown, the G-signal accumulating pixels (pixel regions G₁ to G₁₂) are also similar to those in the imaging device according to the second embodiment. That is, in the imaging device according to the present embodiment, the green color filter 74G is arranged above the pixel regions G₁ to G₁₂, the blue color filter 74B is arranged above the pixel regions B/R₁ to B/R₉ and the red color filter 74R is arranged above the pixel regions O₁ to O₄.

In the B/R signal accumulating pixels (pixel regions B/R₁ to B/R₉), the second conductivity type impurity diffused layer 60 for isolation is arranged over the entirety. A first conductivity type impurity diffused layer 80 for accumulating the signal charge is provided between this impurity diffusion layer 60 and the impurity diffused layer 62. The impurity diffused layer 80 is isolated from the photodiode (impurity diffused layer 56) by the impurity diffused layer 60. The impurity diffused layer 80 is connected to a source of the transfer MOS transistor of the R-signal reading-out pixel with the transfer gate electrode 12R as the gate electrode. Between the source of this transfer MOS transistor and the first conductivity type impurity diffused layer 56 constituting the photodiode of the B/R signal accumulating pixel (pixel region B/R₃), a second conductivity type impurity diffused layer 82 for isolating them is provided. The impurity diffused layer 80 corresponds to the outlet portion 78 in FIG. 8.

The signal reading-out pixels (pixel regions O₁ to O₄) have a role of reading out a pixel signal in a predetermined color. In the example in FIG. 1, the pixel region O₁ and the pixel region O₄ have a role of the G-signal reading-out pixels, the pixel region O₂ has a role of the B-signal reading-out pixel and the pixel region O₃ has a role of the R-signal reading-out pixel.

In the imaging device according to the present embodiment, the signal reading-out pixels (pixel regions O₁ to O₄) further have a role of generating a signal charge by photoelectrically converting red light having transmitted through the red color filter 74R. In the light detection region of the signal reading-out pixels (pixel regions O₁ to O₄), the first conductivity type impurity diffused layer 56 in which the signal charge is accumulated is not formed similarly to the imaging device according to the second embodiment illustrated in FIG. 6. Thus, the signal charge generated by the red light incident to the signal reading-out pixels (pixel regions O₁ to O₄) is accumulated in the impurity diffused layer 80 of the B/R signal accumulating pixels (pixel regions B/R₁ to B/R₉) adjacent in the four diagonal directions. That is, the impurity diffused layer 80 is a charge accumulating portion for accumulating the signal charge.

On the other hand, the B/R signal accumulating pixels (pixel regions B/R₁ to B/R₉) receive the blue light by the blue color filter 74B and generate a signal charge by photoelectric conversion in the semiconductor substrate 50. The signal charge generated by the photoelectric conversion is accumulated in the impurity diffused layer 56. At this time, the impurity diffused layer 80 in which the signal charge based on the red light is accumulated and the impurity diffused layer 56 in which the signal charge based on the blue light is accumulated are separated from each other by the impurity diffused layer 60 arranged between them. Therefore, in the B/R signal accumulating pixels (pixel regions B/R₁ to B/R₉), the signal charge based on the red light and the signal charge based on the blue light can be accumulated separately.

A depth of the blue-signal photoelectric conversion unit for generating the signal charge by the blue light is determined by a depth of this impurity diffused layer 60. In a silicon semiconductor with a large blue-light absorption coefficient, by setting the depth of the impurity diffused layer 60 to approximately not less than 1.5 μm, such a situation can be prevented that the blue light reaches the impurity diffused layer 80 and the blue signal is mixed with the red signal. The impurity diffused layer 80 for accumulating the red signal charge extends from the deep portion of the semiconductor substrate 50 to the surface portion, but its isolation is made by the impurity diffused layer 82 isolating the shallow portion in addition to the impurity diffused layers 58 and 60 for isolation.

In the imaging device according to the present embodiment, unlike the imaging device according to the first to third embodiments, a ratio of the signals of green, red and blue, that is, color distribution of the color filters is 2:1:1. This color distribution is the same as the color distribution of the Bayer arrangement used in general and has higher color resolution than the imaging device according to the first to third embodiments. Moreover, the charge addition of the four pixels in the same color can be made for each color of the prior-art CMOS pixel, and the saturated signal charge amount of at least the green pixel signal can be increased.

In the present embodiment, the example in which the pixel constitution using the B/R signal accumulating pixels is applied to the imaging device according to the second embodiment is illustrated, but it can be applied to the imaging device according to the third embodiment and the signal accumulating unit for AF is formed.

As described above, according to the present embodiment, since the charge addition reading-out can be performed for each of the pixels in the same color, the SN ratio can be improved as compared with the voltage addition reading-out. Moreover, the pixel reading-out time is reduced, and the number of read-out frames per unit time can be increased. Moreover, a photodiode area of the signal accumulating pixel can be increased, and sensitivity and a saturated signal amount of the pixel can be improved. Moreover, the color distribution of each color can be made the same as the color distribution of the Bayer arrangement, and the color resolution can be improved.

### Fifth Embodiment

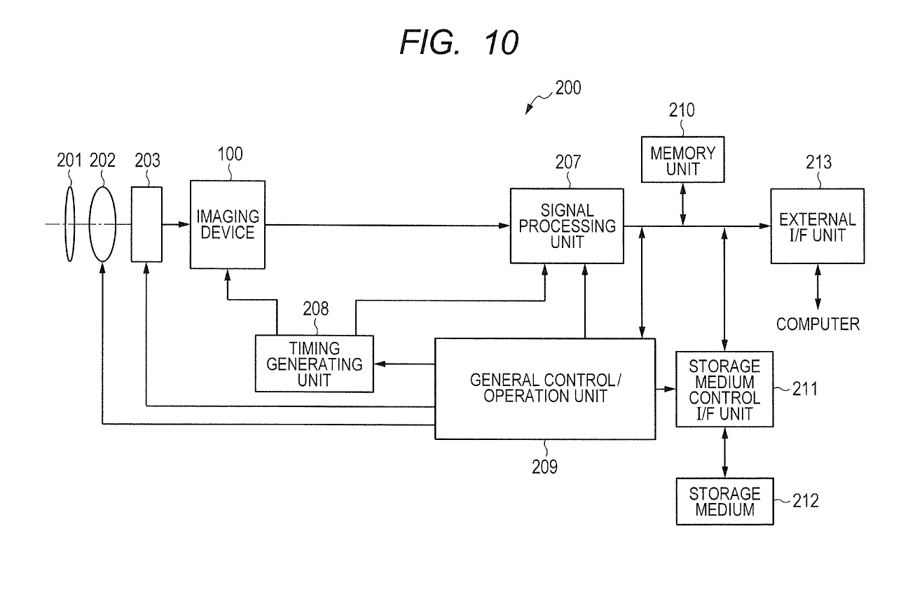

An imaging system according to a fifth embodiment of the present invention will be described with reference to FIG. 10.

FIG. 10 is a diagrammatic view illustrating a constitution example of the imaging system according to the present embodiment. The same reference numerals are given to constituent elements similar to those of the imaging device according to the first to fifth embodiments illustrated in FIGS. 1 to 9 and the description will be omitted or simplified.

The imaging system 200 according to the present embodiment is not particularly limited but can be applied to a digital still camera, digital camcorder, a camera head, a copying machine, a facsimile machine, a mobile phone, an onboard camera, an observation satellite and the like.

The imaging system 200 has the imaging device 100, a lens 202, a diaphragm 203, a barrier 201, a signal processing unit 207, a timing generating unit 208, a general control/operation unit 209, a memory unit 210, a storage medium control I/F unit 211 and an external I/F unit 213.

The lens 202 is for imaging an optical image of an object on the imaging device 100. The diaphragm 203 is for varying a light amount having passed through the lens 202. The barrier 201 is for protecting the lens 202. The imaging device 100 is the imaging device described in the previous embodiments and for converting the optical image imaged by the lens 202 to image data.

The signal processing unit 207 is a signal processing unit for executing various types of correction and processing of data compressing to the image data output from the imaging device 100. An AD conversion unit for AD conversion of the image data may be mounted on the same substrate as the imaging device 100 or may be mounted on another substrate. The signal processing unit 207 may be mounted on the same substrate as the imaging device 100 or may be mounted on another substrate. The timing generating unit 208 is for outputting various timing signals to the imaging device 100 and the signal processing unit 207. The general control/operation unit 209 is a general control unit for controlling the entire imaging system 200. Here, the timing signal and the like may be input from outside the imaging system 200 and the imaging system may have the imaging device 100 and the signal processing unit 207 for processing the image pickup signal output from the imaging device 100.

The memory unit 210 is a frame memory unit for temporarily storing the image data. The storage medium control I/F unit 211 is an interface unit for recording in the storage medium 212 or reading out from the storage medium 212. The storage medium 212 is a detachable recording medium such as a semiconductor memory for recording or reading out from the image data. The external I/F unit 213 is an interface unit for communicating with external computers.

A pixel of the imaging device 100 may be constituted so as to include two photoelectric conversion units (a first photoelectric conversion unit and a second photoelectric conversion unit, for example) as described in the third embodiment. In this case, the signal processing unit 207 may be constituted so as to process the signal based on the charge generated in the first photoelectric conversion unit and the signal based on the charge generated in the second photoelectric conversion unit and to obtain distance information from the imaging device 100 to the object.

By constituting the imaging system to which the imaging device according to the first to fourth embodiments is applied as described above, an image with reduced noise can be obtained.

### Modified Embodiments

The present invention is not limited to the aforementioned embodiments and is capable of various variations.

For example, in the first embodiment, the pixel reading-out circuit including the three types of transistors, that is, the transfer MOS transistor 12, the reset MOS transistor 14 and the amplifier MOS transistor 16 is described as an example, but the constitution of the pixel reading-out circuit is not limited to that. For example, the number of the transistors constituting the pixel reading-out circuits may be four or more such as a circuit constitution having a select transistor between the amplifier MOS transistor 16 and the pixel signal output line 22.

Moreover, in the aforementioned embodiments, the constitution for transferring the signal charge from the four signal accumulating pixels to the one signal reading-out pixel or from the two signal accumulating pixels to the one signal reading-out pixel is illustrated, but the number of pixels to be subjected to the charge addition at one time may be determined arbitrarily. The number of pixels to be added when the charge addition reading-out is performed may be two pixels in the four pixels or three pixels in the four pixels, for example.

Moreover, the imaging system illustrated in the fifth embodiment illustrates an example of the imaging system to which the imaging device of the present invention can be applied and the imaging system to which the imaging device of the present invention can be applied is not limited to the constitution illustrated in FIG. 10.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-182273, filed Sep. 8, 2014, which is hereby incorporated by reference herein in its entirety.

What is claimed is:

1. An imaging device including a plurality of pixel regions arranged in a matrix including a plurality of rows and a plurality of columns, wherein
the plurality of pixel regions includes
a plurality of first pixel regions arranged at every other pixel in each row so that the plurality of first pixel regions alternate with each other in adjacent rows, each of the plurality of first pixel regions being configured to convert light in a first color into a first signal charge and accumulate the first signal charge;
a plurality of second pixel regions arranged in a square lattice form and at positions different from those of the first pixel regions, each of the plurality of second pixel regions being configured to convert light in a second color or a third color different from the first color into a second signal charge and accumulate the second signal charge; and
a plurality of third pixel regions arranged in a square lattice form and at positions different from those of the first pixel regions and the second pixel regions, each of the plurality of third pixel regions having a first reading-out circuit unit configured to add the first signal charge accumulated in at least two first pixel regions adjacent to the third pixel region or add the second signal charge accumulated in at least two second pixel regions corresponding to a same color and being adjacent to the third pixel region and to output a signal based on an amount of added signal charges.

2. The imaging device according to claim 1, further comprising:
a micro lens for collecting light to the first pixel region, wherein
the micro lens is formed so as to extend from above the first pixel region to above the third pixel region; and
an occupied area of the micro lens is larger than an area of the first pixel region.

3. The imaging device according to claim 1, wherein
the third pixel region further includes a photoelectric conversion unit configured to convert light in the second color or the third color into a third signal charge.

4. The imaging device according to claim 3, wherein
the third pixel region further includes a charge accumulating portion; and
at least a part of the third signal charge generated in the photoelectric conversion unit is accumulated in the charge accumulating portion of the third pixel region.

5. The imaging device according to claim 4 wherein
the third pixel region further includes a second reading-out circuit unit configured to output a signal based on the third signal charge accumulated in the charge accumulating portion as a signal for adjusting focal point of a lens.

6. The imaging device according to claim 3, wherein
at least a part of the third signal charge generated in the photoelectric conversion unit of the third pixel region is accumulated in the second pixel region adjacent to the third pixel region.

7. The imaging device according to claim 3, wherein
the light in the second color enters the plurality of second pixel regions and the light in the third color enters the plurality of third pixel regions; and
the second signal charge generated in the second pixel region by the light in the second color and the third signal charge generated in the third pixel region by the light in the third color are separately accumulated in two charge accumulating portions provided in the second pixel region.

8. The imaging device according to claim 1, further comprising:
a well provided in the first pixel region and the second pixel region; and
a contact portion provided in the third pixel region and configured to supply a voltage to the well.

9. The imaging device according to claim 1, wherein
the first color is green;
the second color is blue; and
the third color is red.

10. An imaging device including a plurality of pixel regions arranged in a matrix including a plurality of rows and a plurality of columns, wherein
the plurality of pixel regions includes
a plurality of first pixel regions arranged at every other pixel in each row so that the plurality of first pixel regions alternate with each other in adjacent rows, each of the plurality of first pixel regions being configured to convert light in a first color into a first signal charge and accumulate the first signal charge;
a plurality of second pixel regions arranged in a square lattice form and at positions different from those of the first pixel regions, each of the plurality of second pixel regions being configured to convert light in a color different from the first color and accumulate the second signal charge; and
a plurality of third pixel regions arranged in the square lattice form and at positions different from those of the first pixel regions and the second pixel regions, each of the plurality of third pixel regions including a reading-out circuit unit configured to output a signal based on an amount of the first signal charge accumulated in the first pixel region or a signal based on an amount of the second signal charge accumulated in the second pixel region.

11. An imaging system comprising:
an imaging device including a plurality of pixel regions arranged in a matrix including a plurality of rows and a plurality of columns, wherein
the plurality of pixel regions includes
a plurality of first pixel regions arranged at every other pixel in each row so that the plurality of first pixel regions alternate with each other in adjacent rows, each of the plurality of first pixel regions being configured to convert light in a first color into a first signal charge and accumulate the first signal charge;
a plurality of second pixel regions arranged in a square lattice form and at positions different from those of the first pixel regions, each of the plurality of second pixel regions being configured to convert light in a second color or a third color different from the first color into a second signal charge and accumulate the second signal charge; and
a plurality of third pixel regions arranged in a square lattice form and at positions different from those of the first pixel regions and the second pixel regions, each of the plurality of third pixel regions having a first reading-out circuit unit configured to add the first signal charge accumulated in at least two first pixel regions adjacent to the third pixel region or add the second signal charge accumulated in at least two second pixel regions corresponding to a same color and being adjacent to the third pixel region and to output a signal based on an amount of added signal charges; and
a signal processing unit for processing the signal output from the imaging device.
